(19) United States
(12) Patent Application Publication
(10) Pub. No.: US 2026/0304874 A1
(43) Pub. Date: Oct. 1, 2026

(54) SILICON CARBIDE SUBSTRATE, SILICON CARBIDE SEMICONDUCTOR DEVICE, AND METHOD FOR MANUFACTURING SILICON CARBIDE SUBSTRATE

(71) Applicant: SUMITOMO ELECTRIC INDUSTRIES, LTD., Osaka (JP)

(72) Inventor: Kosuke UCHIDA, Osaka (JP)

(21) Appl. No.: 19/475,641

(22) PCT Filed: Apr. 16, 2024
(86) PCT No.: PCT/JP2024/015148

§ 371 Date: Oct. 15, 2025

(30) Foreign Application Priority Data
Jun. 8, 2023 (JP) 2023-094793

(51) Int. Cl. H10D 62/60; H10D 30/66; H10D 62/832; H10P 30/20

(52) U.S. Cl. CPC H10D 62/60; H10D 30/668; H10D 62/8325; H10P 30/2042

(57) ABSTRACT

A silicon carbide substrate includes a silicon carbide single crystal substrate having a first conductivity type; a silicon carbide epitaxial layer provided over the silicon carbide single crystal substrate and having the first conductivity type; and a drift layer provided over the silicon carbide epitaxial layer and having the first conductivity type. The silicon carbide epitaxial layer includes a first region and a second region.

The first region is located over the second region.

An impurity concentration of the first region is higher than an impurity concentration of the silicon carbide single crystal substrate. An impurity concentration of the second region is higher than the impurity concentration of the first region.

### TECHNICAL FIELD

The present disclosure relates to a silicon carbide substrate, a silicon carbide semiconductor device, and a method for manufacturing a silicon carbide substrate.

The present application claims priority to Japanese Patent Application No. 2023-094793, filed on Jun. 8, 2023, and the entire contents of this Japanese patent application are incorporated herein by reference.

### BACKGROUND ART

A silicon carbide epitaxial substrate including, between a silicon carbide single crystal substrate and a silicon carbide epitaxial layer, a recombination promoting layer (silicon carbide epitaxial layer) having an impurity concentration higher than that of the silicon carbide single crystal substrate is disclosed. By provision of the silicon carbide epitaxial layer, an occurrence of stacking faults due to a basal plane dislocation included in the silicon carbide single crystal substrate is suppressed.

### CITATION LIST

### Patent Literature

Patent Literature 1: International Publication No. WO2017/094764

### SUMMARY OF THE INVENTION

A silicon carbide substrate according to the present disclosure includes: a silicon carbide single crystal substrate having a first conductivity type; a silicon carbide epitaxial layer provided over the silicon carbide single crystal substrate and having the first conductivity type; and a drift layer provided over the silicon carbide epitaxial layer and having the first conductivity type. The silicon carbide epitaxial layer includes a first region and a second region. The first region is located over the second region. An impurity concentration of the first region is higher than an impurity concentration of the silicon carbide single crystal substrate. An impurity concentration of the second region is higher than the impurity concentration of the first region.

### BRIEF DESCRIPTION OF THE DRAWINGS

FIG. 1 is a cross-sectional diagram illustrating a silicon carbide semiconductor device according to an embodiment.

FIG. 2 is a diagram illustrating a silicon carbide substrate according to a first example of the embodiment.

FIG. 3 is a diagram illustrating a silicon carbide substrate according to a second example of the embodiment.

FIG. 4 is a diagram illustrating a silicon carbide substrate according to a third example of the embodiment.

FIG. 5 is a diagram illustrating a silicon carbide substrate according to a fourth example of the embodiment.

FIG. 6 is a diagram illustrating a silicon carbide substrate according to a fifth example of the embodiment.

FIG. 7 is a diagram illustrating a silicon carbide substrate according to a sixth example of the embodiment.

### DETAILED DESCRIPTION OF THE DISCLOSURE

### Objects To Be Solved By The Present Disclosure

For making a silicon carbide epitaxial layer thin, it is effective to increase an impurity concentration of the silicon carbide epitaxial layer. However, when the impurity concentration of the silicon carbide epitaxial layer is increased, stacking faults are readily formed in the silicon carbide epitaxial layer due to crystal distortion. When such stacking faults are formed, the stacking faults are extended to a drift layer formed over the silicon carbide epitaxial layer.

It is an object of the present disclosure to provide a silicon carbide substrate, a silicon carbide semiconductor device, and a method for manufacturing the silicon carbide semiconductor device, which can improve recombination efficiency and reduce a required thickness of a silicon carbide epitaxial layer.

### Effects of Present Disclosure

According to the present disclosure, it is possible to provide a silicon carbide substrate, a silicon carbide semiconductor device, and a method for manufacturing the silicon carbide semiconductor device, which can improve recombination efficiency and reduce a required thickness of a silicon carbide epitaxial layer.

Embodiments will be described below.

### Description Of Embodiments Of Present Disclosure

First, embodiments of the present disclosure will be listed and described. In the following description, the same or corresponding components are indicated by the same symbols, and the same description thereof is not repeated.
[1] A silicon carbide substrate according to one aspect of the present disclosure includes: a silicon carbide single crystal substrate having a first conductivity type; a silicon carbide epitaxial layer provided over the silicon carbide single crystal substrate and having the first conductivity type; and a drift layer provided over the silicon carbide epitaxial layer and having the first conductivity type. The silicon carbide epitaxial layer includes a first region and a second region.

The first region is located over the second region.

An impurity concentration of the first region is higher than an impurity concentration of the silicon carbide single crystal substrate. An impurity concentration of the second region is higher than the impurity concentration of the first region. In this case, since the impurity concentration of the outermost surface of the silicon carbide epitaxial layer is low, stacking faults are not readily formed in the outermost surface of the silicon carbide epitaxial layer. Therefore, transfer of the stacking faults from the silicon carbide epitaxial layer to the drift layer is suppressed. Also, since a region having a high impurity concentration exists in the silicon carbide epitaxial layer, recombination of carriers is promoted. This can improve recombination efficiency, and reduce a required thickness of the silicon carbide epitaxial layer.
[2] In [1], the silicon carbide epitaxial layer may include a third region provided between the silicon carbide single crystal substrate and the second region, and an impurity concentration of the third region may be same as the impurity concentration of the first region. In this case, due to the third region having a concentration lower than that of the second region, lattice mismatch with the silicon carbide single crystal substrate is reduced, thereby enabling suppression of generation of defects.
[3] In [1] or [2], the silicon carbide substrate may include a buffer layer provided between the silicon carbide single crystal substrate and the silicon carbide epitaxial layer and having the first conductivity type, and an impurity concentration of the buffer layer may be lower than the impurity concentration of the silicon carbide single crystal substrate. In this case, when the buffer layer is epitaxially grown on the silicon carbide single crystal substrate, a basal plane dislocation (BPD) existing in the silicon carbide single crystal substrate is readily converted into a threading edge dislocation (TED) at the interface between the silicon carbide single crystal substrate and the buffer layer. Therefore, it is possible to suppress the basal plane dislocation reaching the drift layer. As a result, extension of stacking faults in the drift layer when energizing a pn junction in the forward direction is suppressed, resulting in enabling suppression of an increase in an ON voltage.
[4] A silicon carbide substrate according to another aspect of the present disclosure includes: a silicon carbide single crystal substrate having a first conductivity type; a buffer layer provided over the silicon carbide single crystal substrate and having the first conductivity type; and a drift layer provided over the buffer layer and having the first conductivity type. The buffer layer includes a fourth region and a fifth region. The fourth region is located over the fifth region. An impurity concentration of the fourth region is lower than an impurity concentration of the silicon carbide single crystal substrate. An impurity concentration of the fifth region is higher than the impurity concentration of the silicon carbide single crystal Substrate. In this case, since the impurity concentration of the outermost surface of the buffer layer is low, stacking faults are not readily formed in the outermost surface of the buffer layer.

Therefore, transfer of the stacking faults from the buffer layer to the drift layer is suppressed. Also, since a region having a high impurity concentration exists in the buffer layer, recombination of carriers is promoted. This can improve recombination efficiency, and reduce a required thickness of the buffer layer.
[5] In [4], the buffer layer may include a sixth region provided between the silicon carbide single crystal substrate and the fifth region, and an impurity concentration of the sixth region may be same as the impurity concentration of the fourth region. In this case, due to the sixth region having a concentration lower than that of the fifth region, lattice mismatch with the silicon carbide single crystal substrate is reduced, thereby enabling suppression of generation of defects.
[6] A silicon carbide semiconductor device according to another aspect of the present disclosure includes a silicon carbide substrate including a first main surface and a second main surface opposite to the first main surface. The silicon carbide substrate includes a silicon carbide single crystal substrate having a first conductivity type, a silicon carbide epitaxial layer provided over the silicon carbide single crystal substrate and having the first conductivity type, and a drift layer provided over the silicon carbide epitaxial layer and having the first conductivity type. The silicon carbide epitaxial layer includes a first region and a second region. The first region is located over the second region. An impurity concentration of the first region is higher than an impurity concentration of the silicon carbide single crystal substrate. An impurity concentration of the second region is higher than the impurity concentration of the first region. In this case, since the impurity concentration of the outermost surface of the silicon carbide epitaxial layer is low, stacking faults are not readily formed in the outermost surface of the silicon carbide epitaxial layer. Therefore, transfer of the stacking faults from the silicon carbide epitaxial layer to the drift layer is suppressed. Also, since a region having a high impurity concentration exists in the silicon carbide epitaxial layer, recombination of carriers is promoted. This can improve recombination efficiency, and reduce a required thickness of the silicon carbide epitaxial layer.
[7] A silicon carbide semiconductor device according to another aspect of the present disclosure includes a silicon carbide substrate including a first main surface and a second main surface opposite to the first main surface. The silicon carbide substrate includes a silicon carbide single crystal substrate having a first conductivity type, a buffer layer provided over the silicon carbide single crystal substrate and having the first conductivity type, and a drift layer provided over the buffer layer and having the first conductivity type. The buffer layer includes a fourth region and a fifth region. The fourth region is located over the fifth region. An impurity concentration of the fourth region is lower than an impurity concentration of the silicon carbide single crystal substrate. An impurity concentration of the fifth region is higher than the impurity concentration of the silicon carbide single crystal substrate. In this case, since the impurity concentration of the outermost surface of the buffer layer is low, stacking faults are not readily formed in the outermost surface of the buffer layer. Therefore, transfer of the stacking faults from the buffer layer to the drift layer is suppressed. Also, since a region having a high impurity concentration exists in the buffer layer, recombination of carriers is promoted. This can improve recombination efficiency, and reduce a required thickness of the buffer layer.
[8] A method for manufacturing a silicon carbide substrate according to another aspect of the present disclosure includes: forming, over a silicon carbide single crystal substrate having a first conductivity type, a silicon carbide epitaxial layer having the first conductivity type and having an impurity concentration higher than an impurity concentration of the silicon carbide single crystal substrate; forming a second region having the first conductivity type at a position apart from an upper surface of the silicon carbide epitaxial layer through ion implantation into the silicon carbide epitaxial layer; and after the formation of the second region, forming a drift layer having the first conductivity type over the silicon carbide epitaxial layer. As the second region is formed, a first region is formed over the second region of the silicon carbide epitaxial layer. An impurity concentration of the first region is higher than an impurity concentration of the silicon carbide single crystal substrate. An impurity concentration of the second region is higher than the impurity concentration of the first region. In this case, since the impurity concentration of the outermost surface of the silicon carbide epitaxial layer is low, stacking faults are not readily formed in the outermost surface of the silicon carbide epitaxial layer. Therefore, transfer of the stacking faults from the silicon carbide epitaxial layer to the drift layer is suppressed. Also, since a region having a high impurity concentration exists in the silicon carbide epitaxial layer, recombination of carriers is promoted. This can improve recombination efficiency, and reduce a required thickness of the silicon carbide epitaxial layer.
[9] A method for manufacturing a silicon carbide substrate according to another aspect of the present disclosure includes: forming, over a silicon carbide single crystal substrate having a first conductivity type, a buffer layer having the first conductivity type and having an impurity concentration lower than an impurity concentration of the silicon carbide single crystal substrate; forming a fifth region having the first conductivity type at a position apart from an upper surface of the buffer layer through ion implantation into the buffer layer; and after the formation of the fifth region, forming a drift layer having the first conductivity type over the buffer layer. As the fifth region is formed, a fourth region is formed over the fifth region of the buffer layer. An impurity concentration of the fourth region is lower than an impurity concentration of the silicon carbide single crystal substrate. An impurity concentration of the fifth region is higher than the impurity concentration of the silicon carbide single crystal substrate. In this case, since the impurity concentration of the outermost surface of the buffer layer is low, stacking faults are not readily formed in the outermost surface of the buffer layer. Therefore, transfer of the stacking faults from the buffer layer to the drift layer is suppressed. Also, since a region having a high impurity concentration exists in the buffer layer, recombination of carriers is promoted. This can improve recombination efficiency, and reduce a required thickness of the buffer layer.

### Details Of Embodiments Of Present Disclosure

Embodiments of the present disclosure will be described in detail below. However, the present disclosure is not limited thereto.

### Silicon Carbide Semiconductor Device

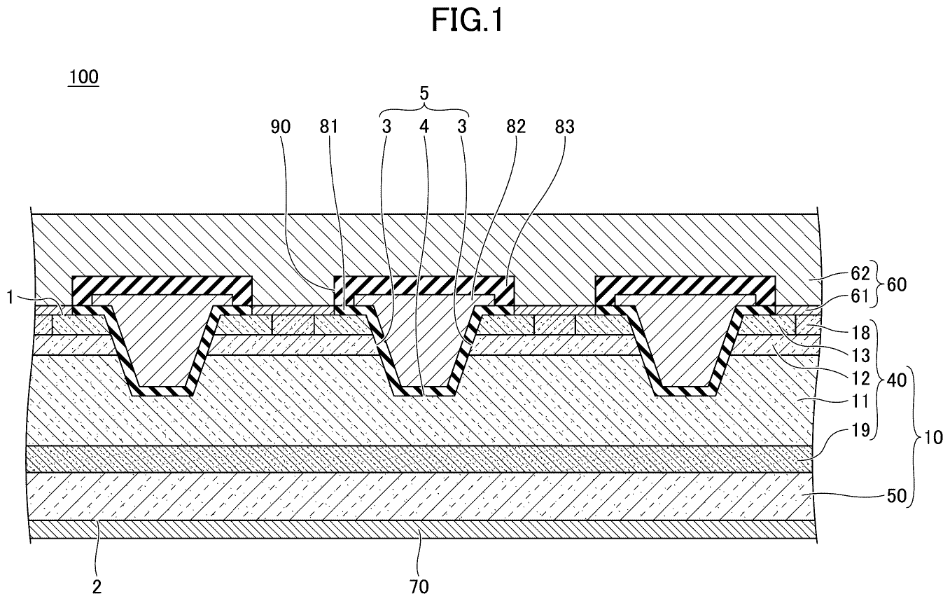

A silicon carbide semiconductor device 100 according to an embodiment will be described. FIG. 1 is a cross-sectional diagram illustrating the silicon carbide semiconductor device 100 according to the embodiment.

The silicon carbide semiconductor device 100 mainly includes a silicon carbide substrate 10, a gate insulating film 81, a gate electrode 82, an interlayer insulating film 83, a source electrode 60, and a drain electrode 70.

The silicon carbide substrate 10 includes a silicon carbide single crystal substrate 50 and a silicon carbide epitaxial layer 40 located over the silicon carbide single crystal substrate 50. The silicon carbide substrate 10 includes a first main surface 1 and a second main surface 2 opposite to the first main surface 1. The silicon carbide epitaxial layer 40 forms the first main surface 1, and the silicon carbide single crystal substrate 50 forms the second main surface 2. The silicon carbide single crystal substrate 50 and the silicon carbide epitaxial layer 40 are formed, for example, of hexagonal silicon carbide of Polytype 4H. The silicon carbide single crystal substrate 50 is n-type due to containing n-type impurities, such as nitrogen (N) or the like. A semiconductor element is formed over the silicon carbide substrate 10.

In the embodiment, a field-effect transistor is formed over the silicon carbide substrate 10 as an example of the semiconductor element. The silicon carbide epitaxial layer 40 mainly includes a drift region 11, a body region 12, a source region 13, a contact region 18, and a recombination promoting layer 19.

The drift region 11 is n-type due to containing n-type impurities, such as nitrogen, phosphorus (P), or the like.

The body region 12 is provided over the drift region 11. The body region 12 is p-type due to containing p-type impurities, such as aluminum (Al) or the like.

The source region 13 is provided over the body region 12 to be separated from the drift region 11 by the body region 12. The source region 13 is n-type due to containing n-type impurities, such as nitrogen, phosphorus, or the like. The source region 13 forms the first main surface 1.

The contact region 18 is p-type due to containing p-type impurities, such as aluminum or the like. The contact region 18 forms the first main surface 1. The contact region 18 penetrates through the source region 13, and contacts the body region 12.

The recombination promoting layer 19 is provided over the silicon carbide single crystal substrate 50. The recombination promoting layer 19 is provided between the silicon carbide single crystal substrate 50 and the drift region 11. Details of the recombination promoting layer 19 will be described below.

The first main surface 1 includes a plurality of gate trenches 5. The gate trenches 5 extend, for example, in a first direction parallel to the first main surface 1, and the plurality of gate trenches 5 are arranged in a second direction. Each of the gate trenches 5 includes a bottom surface 4 formed of the drift region 11. The bottom surface 4 is, for example, a plane parallel to the second main surface 2. The gate trench 5 includes a side surface 3 penetrating through the source region 13 and the body region 12 to be continuous with the bottom surface 4. The side surface 3 is inclined relative to a plane including the bottom surface 4.

The gate insulating film 81 is in contact with the side surface 3 and the bottom surface 4. The gate insulating film 81 is, for example, an oxide film. The gate insulating film 81 is formed, for example, of a material including silicon dioxide. The gate insulating film 81 is in contact with the drift region 11 at the bottom surface 4. The gate insulating film 81 is in contact with each of the source region 13, the body region 12, and the drift region 11 at the side surface 3. The gate insulating film 81 may be in contact with the source region 13 at the first main surface 1.

The gate electrode 82 is provided over the gate insulating film 81. The gate electrode 82 is formed, for example, of polysilicon containing conductive impurities. The gate electrode 82 is disposed in the gate trench 5.

The interlayer insulating film 83 is in contact with the gate electrode 82 and the gate insulating film 81. The interlayer insulating film 83 is formed, for example, of a material containing silicon dioxide. Contact holes 90 are formed in the interlayer insulating film 83 and the gate insulating film 81 at regular intervals in the second direction. The contact holes 90 are provided such that the gate trench 5 is positioned between the contact holes 90 next to each other in the second direction. The contact holes 90 extend in the first direction. The source region 13 and the contact region 18 are exposed from the interlayer insulating film 83 and the gate insulating film 81 through each of the contact holes 90.

The source electrode 60 is in contact with the first main surface 1. The source electrode 60 includes a contact electrode 61 and a source interconnect 62.

The contact electrode 61 is provided in the contact hole 90. The contact electrode 61 is in contact with the source region 13 and the contact region 18 at the first main surface 1. The contact electrode 61 is formed of a material containing titanium (Ti), aluminum (Al), and silicon (Si). The contact electrode 61 is in ohmic contact with the source region 13 and the contact region 18. The contact electrode 61 is connected to the silicon carbide substrate 10 through the contact hole 90.

The source interconnect 62 is formed of a material containing aluminum or copper (Cu). The source interconnect 62 may be formed of a material containing aluminum and copper. The source electrode 60 is electrically insulated from the gate electrode 82 by the interlayer insulating film 83. The source electrode 60 may include a barrier metal film, such as a titanium nitride (TiN) film or the like, between the source interconnect 62 and the interlayer insulating film 83.

The drain electrode 70 is in contact with the second main surface 2. The drain electrode 70 is in contact with the silicon carbide single crystal substrate 50 at the second main surface 2. The drain electrode 70 is electrically connected to the drift region 11. The drain electrode 70 is formed of the same material as in the contact electrode 61. The drain electrode 70 is in ohmic contact with the silicon carbide single crystal substrate 50.

### Silicon Carbide Substrate

Next, the silicon carbide substrate 10 included in the silicon carbide semiconductor device 100 according to the embodiment will be described.

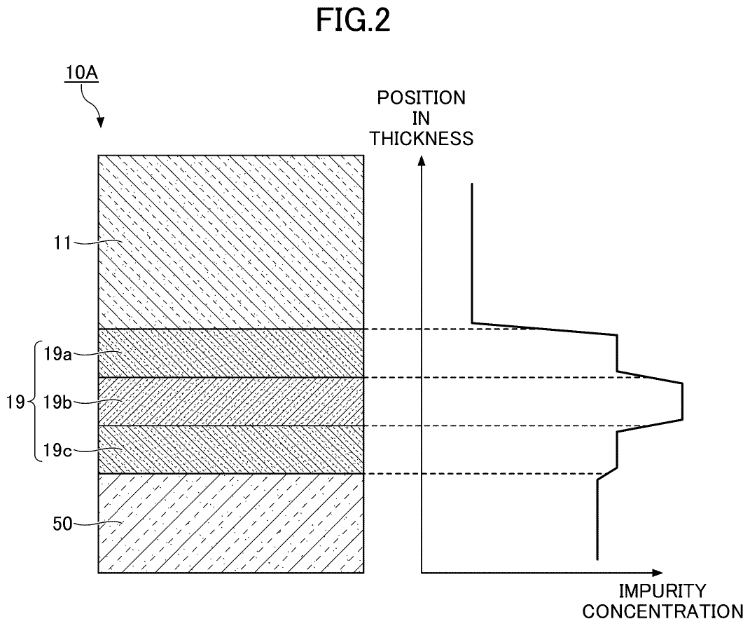

A silicon carbide substrate 10A according to a first example of the embodiment will be described with reference to FIG. 2. FIG. 2 is a diagram illustrating the silicon carbide substrate 10A according to the first example of the embodiment. In FIG. 2, a left diagram illustrates a cross-sectional diagram of the silicon carbide substrate 10A, and a right diagram illustrates an impurity concentration profile of the silicon carbide substrate 10A.

The silicon carbide substrate 10A mainly includes the silicon carbide single crystal substrate 50, the recombination promoting layer 19, and the drift region 11.

The silicon carbide single crystal substrate 50 is n-type due to containing n-type impurities, such as nitrogen or the like. An effective concentration of the n-type impurities in the silicon carbide single crystal substrate 50 is, for example, 1×10¹⁸ cm⁻³ or greater 7×10¹⁸ cm⁻³ or less.

The recombination promoting layer 19 is provided over the silicon carbide single crystal substrate 50. The recombination promoting layer 19 includes a first region 19a, a second region 19b, and a third region 19c.

The first region 19a is provided over the second region 19b. The first region 19a is in contact with the drift region 11. The first region 19a is n-type due to containing n-type impurities, such as nitrogen, phosphorus, or the like. An effective concentration of the n-type impurities in the first region 19a is higher than the effective concentration of the n-type impurities in the silicon carbide single crystal substrate 50. The effective concentration of the n-type impurities in the first region 19a is, for example, 5×10¹⁶ cm⁻³ or greater and 2×10¹⁹ cm⁻³ or less.

The second region 19b is provided over the third region 19c. The second region 19b is provided at a position apart from the upper surface of the recombination promoting layer 19. The second region 19b is provided between the first region 19a and the third region 19c. The second region 19b is n-type due to containing n-type impurities, such as nitrogen, phosphorus, or the like. An effective concentration of the n-type impurities in the second region 19b is higher than the effective concentration of the n-type impurities in the first region 19a. The effective concentration of the n-type impurities in the second region 19b is, for example, 1×10¹⁹ cm⁻³ or greater.

The third region 19c is provided over the silicon carbide single crystal substrate 50. The third region 19c is in contact with the silicon carbide single crystal substrate 50. The third region 19c is n-type due to containing n-type impurities, such as nitrogen, phosphorus, or the like. An effective concentration of the n-type impurities in the third region 19c is, for example, the same as the effective concentration of the n-type impurities in the first region 19a. In this case, the third region 19c has a concentration lower than that of the second region 19b. Therefore, since lattice mismatch with the silicon carbide single crystal substrate 50 is reduced, generation of defects can be suppressed. The effective concentration of the n-type impurities in the third region 19c is, for example, 5×10¹⁸ cm⁻³ or greater and 2×10¹⁹ cm⁻³ or less.

The drift region 11 is provided over the recombination promoting layer 19. The drift region 11 is in contact with the first region 19a. The drift region 11 is n-type due to containing n-type impurities, such as nitrogen, phosphorus, or the like. An effective concentration of the n-type impurities in the drift region 11 is, for example, 1×10¹⁴ cm⁻³ or greater and 5×10¹⁶ cm⁻³ or less.

According to the silicon carbide substrate 10A described above and the silicon carbide semiconductor device 100 including the silicon carbide substrate 10A, the recombination promoting layer 19 includes the first region 19a and the second region 19b. The first region 19a is provided over the second region 19b. The effective concentration of the n-type impurities in the second region 19b is higher than the effective concentration of the n-type impurities in the first region 19a. In this case, since the impurity concentration of the outermost surface region (the first region 19a) of the recombination promoting layer 19 is low, stacking faults are not readily formed in the outermost surface of the recombination promoting layer 19. Therefore, transfer of the stacking faults from the recombination promoting layer 19 to the drift region 11 is suppressed. Also, since a region (the second region 19b) having a high impurity concentration exists in the recombination promoting layer 19, recombination of carriers is promoted. This can improve recombination efficiency, and reduce a required thickness of the recombination promoting layer 19. When the required thickness of the recombination promoting layer 19 is reduced, a period required for epitaxial growth in forming the recombination promoting layer 19 is reduced, and thus manufacturing cost is reduced.

Next, a method for manufacturing the silicon carbide substrate 10A will be described.

First, the silicon carbide single crystal substrate 50 is provided. For example, the silicon carbide single crystal substrate 50 is n-type due to containing n-type impurities, such as nitrogen or the like.

Next, the recombination promoting layer 19 is formed over the silicon carbide single crystal substrate 50. Specifically, the recombination promoting layer 19 is formed over the silicon carbide single crystal substrate 50 through epitaxial growth performed by addition of n-type impurities, such as nitrogen, phosphorus, or the like. Next, ion implantation is performed to the recombination promoting layer 19. Due to the ion implantation, the second region 19b is formed at a position apart from the upper surface of the recombination promoting layer 19. As the second region 19b is formed, the first region 19a is formed over the second region 19b of the recombination promoting layer 19, and the third region 19c is formed under the second region 19b of the recombination promoting layer 19. In the ion implantation for forming the second region 19b, n-type impurities, such as nitrogen, phosphorus, or the like, are implanted.

Next, the silicon carbide epitaxial layer 40 is formed over the recombination promoting layer 19. For example, the silicon carbide epitaxial layer 40 can be formed through epitaxial growth performed by addition of n-type impurities, such as nitrogen or the like.

Next, ion implantation is performed to the silicon carbide epitaxial layer 40. For example, due to the ion implantation, the body region 12, the source region 13, and the contact region 18 are formed. The remaining portion of the silicon carbide epitaxial layer 40 functions as the drift region 11. In the ion implantation for forming the body region 12 or the contact region 18, p-type impurities, such as aluminum or the like, are implanted. In the ion implantation for forming the source region 13, n-type impurities, such as phosphorus or the like, are implanted.

The above-described process can manufacture the silicon carbide substrate 10A in which the recombination promoting layer 19 and the silicon carbide epitaxial layer 40 are formed in this order over the silicon carbide single crystal substrate 50.

According to the method for manufacturing the silicon carbide substrate 10A described above, after the formation of the recombination promoting layer 19 over the silicon carbide single crystal substrate 50, ion implantation is performed to the recombination promoting layer 19, thereby forming the second region 19b at a position apart from the upper surface of the recombination promoting layer 19. As the second region 19b is formed, the first region 19a is formed over the second region 19b of the recombination promoting layer 19. The effective concentration of the n-type impurities in the second region 19b is higher than the effective concentration of the n-type impurities in the first region 19a. In this case, since the impurity concentration of the outermost surface region (the first region 19a) of the recombination promoting layer 19 is low, stacking faults are not readily formed in the outermost surface of the recombination promoting layer 19.

Therefore, transfer of the stacking faults from the recombination promoting layer 19 to the drift region 11 is suppressed. Also, since a region having a high impurity concentration (the second region 19b) exists in the recombination promoting layer 19, recombination of carriers is promoted. This can improve recombination efficiency, and reduce a required thickness of the recombination promoting layer 19. When the required thickness of the recombination promoting layer 19 is reduced, a period required for epitaxial growth in forming the recombination promoting layer 19 is reduced, and thus manufacturing cost is reduced.

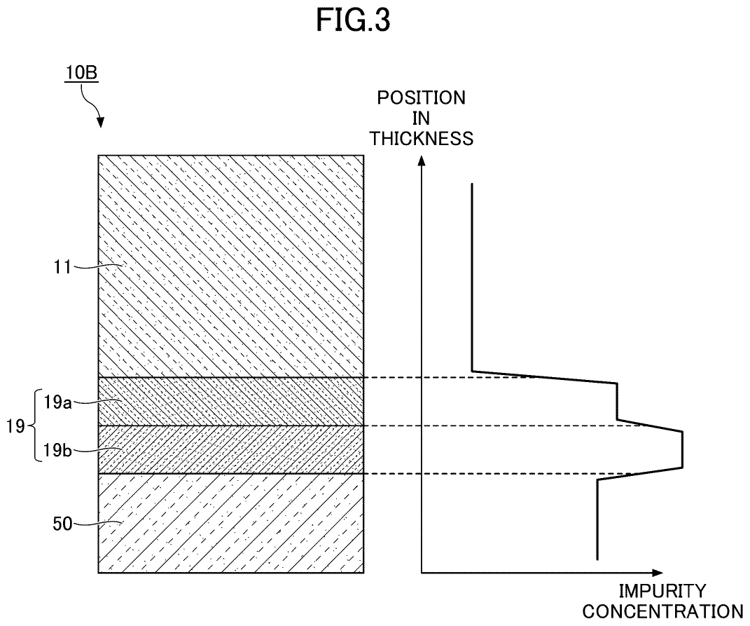

A silicon carbide substrate 10B according to a second example of the embodiment will be described with reference to FIG. 3. FIG. 3 is a diagram illustrating the silicon carbide substrate 10B according to the second example of the embodiment. In FIG. 3, a left diagram illustrates a cross-sectional diagram of the silicon carbide substrate 10B, and a right diagram illustrates an impurity concentration profile of the silicon carbide substrate 10B.

The silicon carbide substrate 10B is different from the silicon carbide substrate 10A in that the recombination promoting layer 19 does not include the third region 19c and includes the first region 19a and the second region 19b. Other configurations of the silicon carbide substrate 10B are, for example, the same as those of the silicon carbide substrate 10A. Hereinafter, the configurations different from those of the silicon carbide substrate 10A will be mainly described.

The recombination promoting layer 19 includes the first region 19a and the second region 19b. The first region 19a is provided over the second region 19b. The first region 19a is in contact with the drift region 11. The second region 19b is provided over the silicon carbide single crystal substrate 50. The second region 19b is provided at a position apart from the upper surface of the recombination promoting layer 19. The second region 19b is in contact with the silicon carbide single crystal substrate 50.

According to the silicon carbide substrate 10B described above and the silicon carbide semiconductor device 100 including the silicon carbide substrate 10B, the recombination promoting layer 19 includes the first region 19a and the second region 19b. The first region 19a is provided over the second region 19b. The effective concentration of the n-type impurities in the second region 19b is higher than the effective concentration of the n-type impurities in the first region 19a. In this case, the same effects as those of the silicon carbide substrate 10A and the silicon carbide semiconductor device 100 including the silicon carbide substrate 10A can be obtained.

The silicon carbide substrate 10B can be manufactured, for example, using the same method as used for the silicon carbide substrate 10A. According to the method for manufacturing the silicon carbide substrate 10B, the same effects as those of the method for manufacturing the silicon carbide substrate 10A can be obtained.

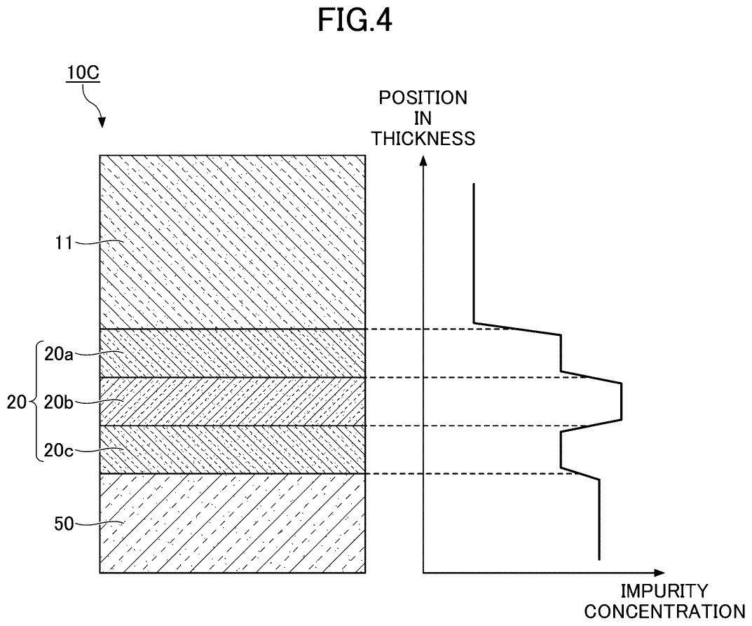

A silicon carbide substrate 10C according to a third example of the embodiment will be described with reference to FIG. 4. FIG. 4 is a diagram illustrating the silicon carbide substrate 10C according to the third example of the embodiment. In FIG. 4, a left diagram illustrates a cross-sectional diagram of the silicon carbide substrate 10C, and a right diagram illustrates an impurity concentration profile of the silicon carbide substrate 10C.

The silicon carbide substrate 10C is different from the silicon carbide substrate 10A in that a buffer layer 20 is provided instead of the recombination promoting layer 19. Other configurations of the silicon carbide substrate 10C are, for example, the same as those of the silicon carbide substrate 10A. Hereinafter, the configurations different from those of the silicon carbide substrate 10A will be mainly described.

The silicon carbide substrate 10C mainly includes the silicon carbide single crystal substrate 50, the buffer layer 20, and the drift region 11.

The buffer layer 20 is provided over the silicon carbide single crystal substrate 50. The buffer layer 20 includes a fourth region 20a, a fifth region 20b, and a sixth region 20c.

The fourth region 20a is provided over the fifth region 20b. The fourth region 20a is in contact with the drift region 11. The fourth region 20a is n-type due to containing n-type impurities, such as nitrogen, phosphorus, or the like. An effective concentration of the n-type impurities in the fourth region 20a is lower than the effective concentration of the n-type impurities in the silicon carbide single crystal substrate 50. The effective concentration of the n-type impurities in the fourth region 20a is, for example, 2×10¹⁷ cm⁻³ or greater and 3×10¹⁸ cm⁻³ or less. The effective concentration of the n-type impurities in the fourth region 20a is substantially constant, and the effective concentration of the n-type impurities may be abruptly switched from the concentration in the fourth region 20a to the concentration in the drift region 11 at the interface between the fourth region 20a and the drift region 11. In this case, resistance of the silicon carbide semiconductor device 100 is unlikely to increase. Conversely, when the effective concentration of the n-type impurities in the fourth region 20a continuously decreases toward the drift region 11, resistance of the silicon carbide semiconductor device 100 is likely to increase.

The fifth region 20b is provided over the sixth region 20c. The fifth region 20b is provided at a position apart from the upper surface of the buffer layer 20. The fifth region 20b is provided between the fourth region 20a and the sixth region 20c. The fifth region 20b is n-type due to containing n-type impurities, such as nitrogen, phosphorus, or the like. An effective concentration of the n-type impurities in the fifth region 20b is higher than the effective concentration of the n-type impurities in the silicon carbide single crystal substrate 50. The effective concentration of the n-type impurities in the fifth region 20b is, for example, 1×10¹⁹ cm⁻³ or greater.

The sixth region 20c is provided over the silicon carbide single crystal substrate 50. The sixth region 20c is in contact with the silicon carbide single crystal substrate 50. The sixth region 20c is n-type due to containing n-type impurities, such as nitrogen, phosphorus, or the like. An effective concentration of the n-type impurities in the sixth region 20c is, for example, the same as the effective concentration of the n-type impurities in the fourth region 20a. In this case, the sixth region 20c has a concentration lower than that of the fifth region 20b. Therefore, since lattice mismatch with the silicon carbide single crystal substrate 50 is reduced, generation of defects can be suppressed. The effective concentration of the n-type impurities in the sixth region 20c is, for example, 2×10¹⁷ cm⁻³ or greater and 3×10¹⁸ cm⁻³ or less.

The drift region 11 is provided over the buffer layer 20. The drift region 11 is in contact with the fourth region 20a. The drift region 11 is n-type due to containing n-type impurities, such as nitrogen, phosphorus, or the like. An effective concentration of the n-type impurities in the drift region 11 is, for example, 1×10¹⁴ cm⁻³ or greater and 5×10¹⁶ cm⁻³ or less.

According to the silicon carbide substrate 10C described above and the silicon carbide semiconductor device 100 including the silicon carbide substrate 10C, the buffer layer 20 includes the fourth region 20a and the fifth region 20b. The fourth region 20a is provided over the fifth region 20b. The effective concentration of the n-type impurities in the fifth region 20b is higher than the effective concentration of the n-type impurities in the fourth region 20a. In this case, since the impurity concentration of the outermost surface region (the fourth region 20a) of the buffer layer 20 is low, stacking faults are not readily formed in the outermost surface of the buffer layer 20. Therefore, transfer of the stacking faults from the buffer layer 20 to the drift region 11 is suppressed. Also, since a region having a high impurity concentration (the fifth region 20b) exists in the buffer layer 20, recombination of carriers is promoted. This can improve recombination efficiency, and reduce a required thickness of the buffer layer 20. When the required thickness of the buffer layer 20 is reduced, a period required for epitaxial growth in forming the buffer layer 20 is reduced, and thus manufacturing cost is reduced.

Next, a method for manufacturing the silicon carbide substrate 10C will be described.

First, the silicon carbide single crystal substrate 50 is provided. For example, the silicon carbide single crystal substrate 50 is n-type due to containing n-type impurities, such as nitrogen or the like.

Next, the buffer layer 20 is formed over the silicon carbide single crystal substrate 50.

Specifically, the buffer layer 20 is formed over the silicon carbide single crystal substrate 50 through epitaxial growth performed by addition of n-type impurities, such as nitrogen, phosphorus, or the like. Next, ion implantation is performed to the buffer layer 20. Due to the ion implantation, the fifth region 20b is formed at a position apart from the upper surface of the buffer layer 20. As the fifth region 20b is formed, the fourth region 20a is formed over the fifth region 20b of the buffer layer 20, and the sixth region 20c is formed under the fifth region 20b of the buffer layer 20. In the ion implantation for forming the fifth region 20b, n-type impurities, such as nitrogen, phosphorus, or the like, are implanted.

Next, the silicon carbide epitaxial layer 40 is formed over the buffer layer 20. A method for forming the silicon carbide epitaxial layer 40 may be the same as the method for forming the silicon carbide epitaxial layer 40 in the method for manufacturing the silicon carbide substrate 10A.

The above-described process can manufacture the silicon carbide substrate 10C in which the buffer layer 20 and the silicon carbide epitaxial layer 40 are formed in this order over the silicon carbide single crystal substrate 50.

According to the method for manufacturing the silicon carbide substrate 10C described above, after the formation of the buffer layer 20 over the silicon carbide single crystal substrate 50, ion implantation is performed to the buffer layer 20, thereby forming the fifth region 20b at a position apart from the upper surface of the buffer layer 20. As the fifth region 20b is formed, the fourth region 20a is formed over the fifth region 20b of the buffer layer 20. The effective concentration of the n-type impurities in the fifth region 20b is higher than the effective concentration of the n-type impurities in the fourth region 20a. In this case, since the impurity concentration of the outermost surface region (the fourth region 20a) of the buffer layer 20 is low, stacking faults are not readily formed in the outermost surface of the buffer layer 20. Therefore, transfer of the stacking faults from the buffer layer 20 to the drift region 11 is suppressed. Also, since a region having a high impurity concentration (the fifth region 20b) exists in the buffer layer 20, recombination of carriers is promoted. This can improve recombination efficiency, and reduce a required thickness of the buffer layer 20. When the required thickness of the buffer layer 20 is reduced, a period required for epitaxial growth in forming the buffer layer 20 is reduced, and thus manufacturing cost is reduced.

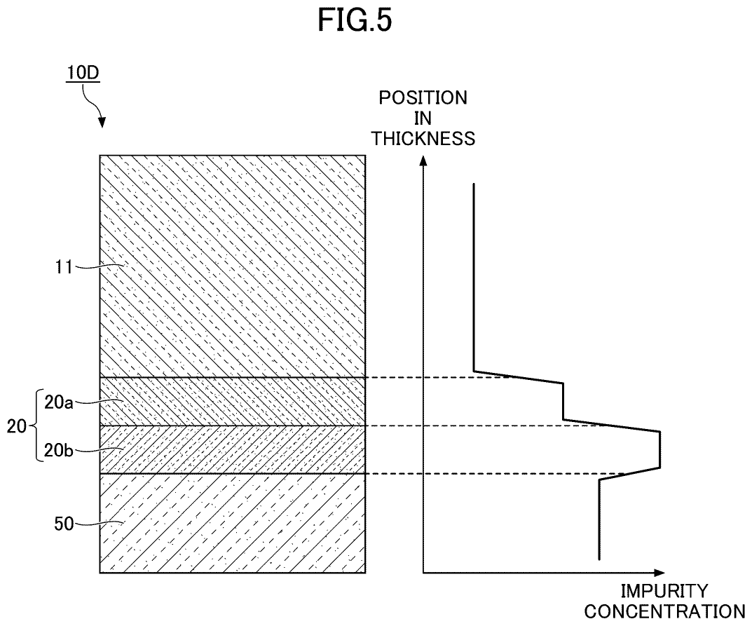

A silicon carbide substrate 10D according to a fourth example of the embodiment will be described with reference to FIG. 5. FIG. 5 is a diagram illustrating the silicon carbide substrate 10D according to the fourth example of the embodiment. In FIG. 5, a left diagram illustrates a cross-sectional diagram of the silicon carbide substrate 10D, and a right diagram illustrates an impurity concentration profile of the silicon carbide substrate 10D.

The silicon carbide substrate 10D is different from the silicon carbide substrate 10C in that the buffer layer 20 does not include the sixth region 20c and includes the fourth region 20a and the fifth region 20b. Other configurations of the silicon carbide substrate 10D are, for example, the same as those of the silicon carbide substrate 10C. Hereinafter, the configurations different from those of the silicon carbide substrate 10C will be mainly described.

The buffer layer 20 includes the fourth region 20a and the fifth region 20b. The fourth region 20a is provided over the fifth region 20b. The fourth region 20a is in contact with the drift region 11. The fifth region 20b is provided over the silicon carbide single crystal substrate 50. The fifth region 20b is provided at a position apart from the upper surface of the recombination promoting layer 19. The fifth region 20b is in contact with the silicon carbide single crystal substrate 50.

According to the silicon carbide substrate 10D described above and the silicon carbide semiconductor device 100 including the silicon carbide substrate 10D, the buffer layer 20 includes the fourth region 20a and the fifth region 20b. The fourth region 20a is provided over the fifth region 20b. The effective concentration of the n-type impurities in the fifth region 20b is higher than the effective concentration of the n-type impurities in the fourth region 20a. In this case, the same effects as those of the silicon carbide substrate 10C and the silicon carbide semiconductor device 100 including the silicon carbide substrate 10C can be obtained.

The silicon carbide substrate 10D can be manufactured, for example, by the same method as in the silicon carbide substrate 10C. According to the method for manufacturing the silicon carbide substrate 10D, the same effects as those of the method for manufacturing the silicon carbide substrate 10C can be obtained.

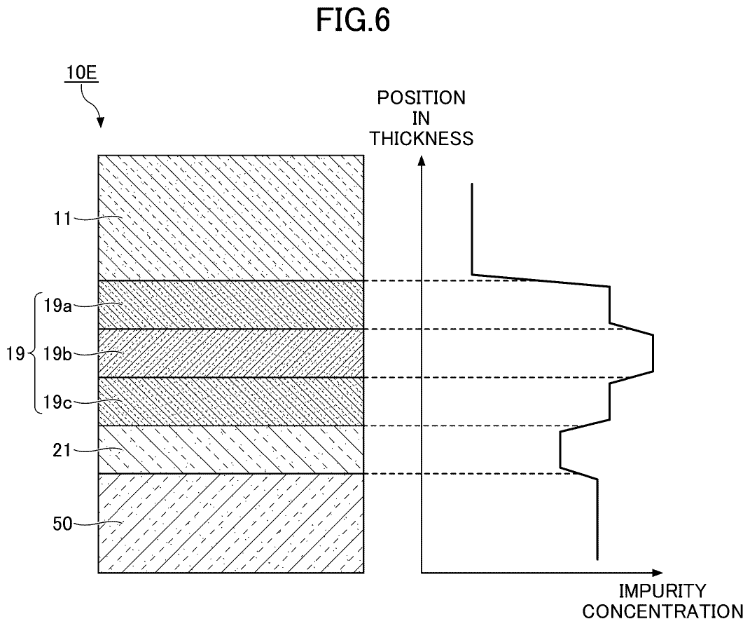

A silicon carbide substrate 10E according to a fifth example of the embodiment will be described with reference to FIG. 6. FIG. 6 is a diagram illustrating the silicon carbide substrate 10E according to the fifth example of the embodiment. In FIG. 6, a left diagram illustrates a cross-sectional diagram of the silicon carbide substrate 10E, and a right diagram illustrates an impurity concentration profile of the silicon carbide substrate 10E.

The silicon carbide substrate 10E is different from the silicon carbide substrate 10A in that the buffer layer 21 is provided between the silicon carbide single crystal substrate 50 and the recombination promoting layer 19. Other configurations of the silicon carbide substrate 10E are, for example, the same as those of the silicon carbide substrate 10A. Hereinafter, the configurations different from those of the silicon carbide substrate 10A will be mainly described.

The silicon carbide substrate 10E mainly includes the silicon carbide single crystal substrate 50, the buffer layer 21, the recombination promoting layer 19, and the drift region 11.

The buffer layer 21 is provided over the silicon carbide single crystal substrate 50. The buffer layer 21 is provided between the silicon carbide single crystal substrate 50 and the recombination promoting layer 19. The buffer layer 21 is n-type due to containing n-type impurities, such as nitrogen, phosphorus, or the like. The effective concentration of the n-type impurities in the buffer layer 21 is lower than the effective concentration of the n-type impurities in the silicon carbide single crystal substrate 50. The effective concentration of the n-type impurities in the buffer layer 21 is, for example, 2×10¹⁷ cm⁻³ or greater and 3×10¹⁸ cm⁻³ or less.

According to the silicon carbide substrate 10E described above and the silicon carbide semiconductor device 100 including the silicon carbide substrate 10E, the recombination promoting layer 19 includes the first region 19a and the second region 19b. The first region 19a is provided over the second region 19b. The effective concentration of the n-type impurities in the second region 19b is higher than the effective concentration of the n-type impurities in the first region 19a. In this case, the same effects as those of the silicon carbide substrate 10A and the silicon carbide semiconductor device 100 including the silicon carbide substrate 10A can be obtained.

Also, according to the silicon carbide substrate 10E and the silicon carbide semiconductor device 100 including the silicon carbide substrate 10E, the buffer layer 21 is provided between the silicon carbide single crystal substrate 50 and the recombination promoting layer 19. In this case, when the buffer layer 21 is epitaxially grown on the silicon carbide single crystal substrate 50, a basal plane dislocation existing in the silicon carbide single crystal substrate 50 is readily converted into a threading edge dislocation at the interface between the silicon carbide single crystal substrate 50 and the buffer layer 21. Therefore, it is possible to suppress the basal plane dislocation reaching the drift region 11. As a result, extension of stacking faults in the drift region 11 when energizing a pn junction in the forward direction is suppressed, resulting in enabling suppression of an increase in an ON voltage.

Next, a method for manufacturing the silicon carbide substrate 10E will be described.

First, the silicon carbide single crystal substrate 50 is provided. For example, the silicon carbide single crystal substrate 50 is n-type due to containing n-type impurities, such as nitrogen or the like.

Next, the buffer layer 21 is formed over the silicon carbide single crystal substrate 50. Specifically, the buffer layer 21 is formed over the silicon carbide single crystal substrate 50 through epitaxial growth performed by addition of n-type impurities, such as nitrogen, phosphorus, or the like.

Next, the recombination promoting layer 19 is formed over the buffer layer 21. A method for forming the recombination promoting layer 19 may be the same as the method for forming the recombination promoting layer 19 in the method for manufacturing the silicon carbide substrate 10A.

Next, the silicon carbide epitaxial layer 40 is formed over the recombination promoting layer 19. A method for forming the silicon carbide epitaxial layer 40 may be the same as the method for forming the silicon carbide epitaxial layer 40 in the method for manufacturing the silicon carbide substrate 10A.

The above-described process can manufacture the silicon carbide substrate 10E in which the buffer layer 21 and the silicon carbide epitaxial layer 40 are formed in this order over the silicon carbide single crystal substrate 50.

According to the method for manufacturing the silicon carbide substrate 10E described above, after the formation of the recombination promoting layer 19 over the silicon carbide single crystal substrate 50, ion implantation is performed to the recombination promoting layer 19, thereby forming the second region 19b at a position apart from the upper surface of the recombination promoting layer 19. As the second region 19b is formed, the first region 19a is formed over the second region 19b of the recombination promoting layer 19. The effective concentration of the n-type impurities in the second region 19b is higher than the effective concentration of the n-type impurities in the first region 19a. In this case, the same effects as those of the silicon carbide substrate 10A and the silicon carbide semiconductor device 100 including the silicon carbide substrate 10A can be obtained.

Also, according to the method for manufacturing the silicon carbide substrate 10E, after the formation of the buffer layer 21 over the silicon carbide single crystal substrate 50, the recombination promoting layer 19 is formed over the buffer layer 21. In this case, when the buffer layer 21 is epitaxially grown on the silicon carbide single crystal substrate 50, a basal plane dislocation existing in the silicon carbide single crystal substrate 50 is readily converted into a threading edge dislocation at the interface between the silicon carbide single crystal substrate 50 and the buffer layer 21. Therefore, it is possible to suppress the basal plane dislocation reaching the drift region 11. As a result, extension of stacking faults in the drift region 11 when energizing a pn junction in the forward direction is suppressed, resulting in enabling suppression of an increase in an ON voltage.

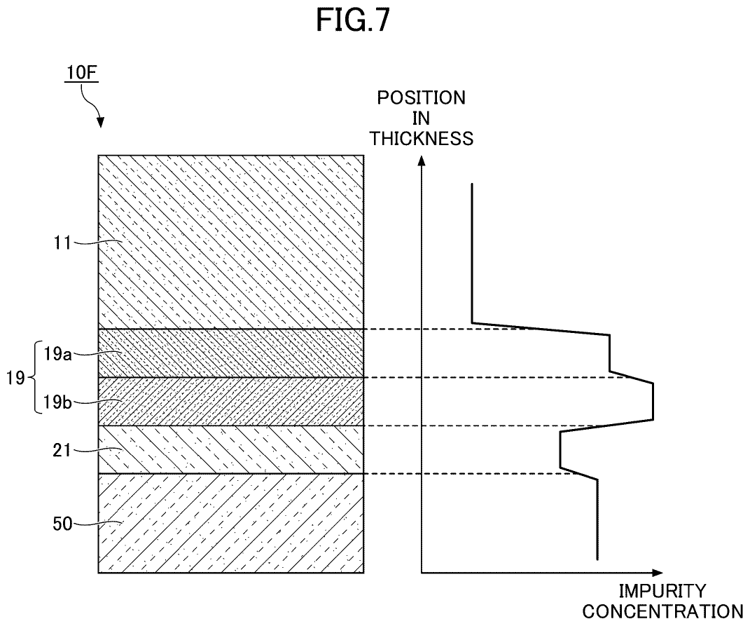

A silicon carbide substrate 10F according to a sixth example of the embodiment will be described with reference to FIG. 7. FIG. 7 is a diagram illustrating the silicon carbide substrate 10F according to the sixth example of the embodiment. In FIG. 7, a left diagram illustrates a cross-sectional diagram of the silicon carbide substrate 10F, and a right diagram illustrates an impurity concentration profile of the silicon carbide substrate 10F.

The silicon carbide substrate 10F is different from the silicon carbide substrate 10E in that the recombination promoting layer 19 does not include the third region 19c and includes the first region 19a and the second region 19b. Other configurations of the silicon carbide substrate 10F are, for example, the same as those of the silicon carbide substrate 10E. Hereinafter, the configurations different from those of the silicon carbide substrate 10E will be mainly described.

The recombination promoting layer 19 includes the first region 19a and the second region 19b. The first region 19a is provided over the second region 19b. The first region 19a is in contact with the drift region 11. The second region 19b is provided over the silicon carbide single crystal substrate 50. The second region 19b is provided at a position apart from the upper surface of the recombination promoting layer 19. The second region 19b is in contact with the silicon carbide single crystal substrate 50.

According to the silicon carbide substrate 10F described above and the silicon carbide semiconductor device 100 including the silicon carbide substrate 10F, the recombination promoting layer 19 includes the first region 19a and the second region 19b. The first region 19a is provided over the second region 19b. The effective concentration of the n-type impurities in the second region 19b is higher than the effective concentration of the n-type impurities in the first region 19a. In this case, the same effects as those of the silicon carbide substrate 10E and the silicon carbide semiconductor device 100 including the silicon carbide substrate 10E can be obtained.

The silicon carbide substrate 10F can be manufactured, for example, by the same method as in the silicon carbide substrate 10E. According to the method for manufacturing the silicon carbide substrate 10F, the same effects as those of the method for manufacturing the silicon carbide substrate 10E can be obtained.

The effective concentration of the p-type impurities and the effective concentration of the n-type impurities in each impurity region described above can be measured by a scanning capacitance microscope (SCM) method, a secondary ion mass spectrometry (SIMS) method, or the like.

Although the embodiments have been described above in detail, no limitation to the specific embodiments is intended. Various modifications and alterations are possible within the scope of claims recited.

### REFERENCE SIGNS LIST

1 First main surface
2 Second main surface
3 Side surface
4 Bottom surface
5 Gate trench
10 Silicon carbide substrate
10A Silicon carbide substrate
10B Silicon carbide substrate
10C Silicon carbide substrate
10D Silicon carbide substrate
10E Silicon carbide substrate
10F Silicon carbide substrate
11 Drift region
12 Body region
13 Source region
18 Contact region
19 Recombination promoting layer
19a First region
19b Second region
19c Third region
20 Buffer layer
20a Fourth region
20b Fifth region
20c Sixth region
21 Buffer layer
40 Silicon carbide epitaxial layer
50 Silicon carbide single crystal substrate
60 Source electrode
61 Contact electrode
62 Source interconnect
70 Drain electrode
81 Gate insulating film
82 Gate electrode
83 Interlayer insulating film
90 Contact hole
100 Silicon carbide semiconductor device

1. A silicon carbide substrate, comprising:
a silicon carbide single crystal substrate having a first conductivity type;
a silicon carbide epitaxial layer provided over the silicon carbide single crystal substrate and having the first conductivity type; and
a drift layer provided over the silicon carbide epitaxial layer and having the first conductivity type, wherein
the silicon carbide epitaxial layer includes a first region and a second region,
the first region is located over the second region,
an impurity concentration of the first region is higher than an impurity concentration of the silicon carbide single crystal substrate, and
an impurity concentration of the second region is higher than the impurity concentration of the first region.

2. The silicon carbide substrate according to claim 1, wherein
the silicon carbide epitaxial layer includes a third region provided between the silicon carbide single crystal substrate and the second region, and
an impurity concentration of the third region is same as the impurity concentration of the first region.

3. The silicon carbide substrate according to claim 1, wherein
the silicon carbide substrate includes a buffer layer provided between the silicon carbide single crystal substrate and the silicon carbide epitaxial layer and having the first conductivity type, and
an impurity concentration of the buffer layer is lower than the impurity concentration of the silicon carbide single crystal substrate.

4. A silicon carbide substrate, comprising:
a silicon carbide single crystal substrate having a first conductivity type;
a buffer layer provided over the silicon carbide single crystal substrate and having the first conductivity type; and
a drift layer provided over the buffer layer and having the first conductivity type, wherein
the buffer layer includes a fourth region and a fifth region,
the fourth region is located over the fifth region,
an impurity concentration of the fourth region is lower than an impurity concentration of the silicon carbide single crystal substrate, and
an impurity concentration of the fifth region is higher than the impurity concentration of the silicon carbide single crystal substrate.

5. The silicon carbide substrate according to claim 4, wherein
the buffer layer includes a sixth region provided between the silicon carbide single crystal substrate and the fifth region, and
an impurity concentration of the sixth region is same as the impurity concentration of the fourth region.

6. A silicon carbide semiconductor device, comprising:
the silicon carbide substrate of claim 1 that further includes a first main surface and a second main surface opposite to the first main surface.

7. A silicon carbide semiconductor device, comprising:
the silicon carbide substrate of claim 4 that further includes a first main surface and a second main surface opposite to the first main surface.

8. A method for manufacturing a silicon carbide substrate, the method comprising:
forming, over a silicon carbide single crystal substrate having a first conductivity type, a silicon carbide epitaxial layer having the first conductivity type and having an impurity concentration higher than an impurity concentration of the silicon carbide single crystal substrate;
forming a second region having the first conductivity type at a position apart from an upper surface of the silicon carbide epitaxial layer through ion implantation into the silicon carbide epitaxial layer; and
after the formation of the second region, forming a drift layer having the first conductivity type over the silicon carbide epitaxial layer, wherein
as the second region is formed, a first region is formed over the second region of the silicon carbide epitaxial layer,
an impurity concentration of the first region is higher than an impurity concentration of the silicon carbide single crystal substrate, and
an impurity concentration of the second region is higher than the impurity concentration of the first region.

9. A method for manufacturing the silicon carbide substrate of claim 4, the method comprising:
forming, over the silicon carbide single crystal substrate having the first conductivity type, the buffer layer having the first conductivity type and having an impurity concentration lower than the impurity concentration of the silicon carbide single crystal substrate;
forming the fifth region having the first conductivity type at a position apart from an upper surface of the buffer layer through ion implantation into the buffer layer; and
after the formation of the fifth region, forming the drift layer having the first conductivity type over the buffer layer, wherein
as the fifth region is formed, the fourth region is formed over the fifth region of the buffer layer,
the impurity concentration of the fourth region is lower than the impurity concentration of the silicon carbide single crystal substrate, and
the impurity concentration of the fifth region is higher than the impurity concentration of the silicon carbide single crystal substrate.

10. The silicon carbide substrate according to claim 2, wherein
the silicon carbide substrate includes a buffer layer provided between the silicon carbide single crystal substrate and the silicon carbide epitaxial layer and having the first conductivity type, and
an impurity concentration of the buffer layer is lower than the impurity concentration of the silicon carbide single crystal substrate.

11. A method for manufacturing the silicon carbide substrate of claim 1, the method comprising:
forming, over the silicon carbide single crystal substrate having the first conductivity type, the silicon carbide epitaxial layer having the first conductivity type and having an impurity concentration higher than the impurity concentration of the silicon carbide single crystal substrate;
forming the second region having the first conductivity type at a position apart from an upper surface of the silicon carbide epitaxial layer through ion implantation into the silicon carbide epitaxial layer; and
after the formation of the second region, forming the drift layer having the first conductivity type over the silicon carbide epitaxial layer, wherein
as the second region is formed, the first region is formed over the second region of the silicon carbide epitaxial layer,
the impurity concentration of the first region is higher than the impurity concentration of the silicon carbide single crystal substrate, and
the impurity concentration of the second region is higher than the impurity concentration of the first region.
